(19) United States
(12) Patent Application Publication
(10) Pub. No.: US 2009/0073736 A1
(43) Pub. Date: Mar. 19, 2009

(54) SEMICONDUCTOR DEVICE HAVING STORAGE NODES ON ACTIVE REGIONS AND METHOD OF FABRICATING THE SAME

(75) Inventors: Min-Hee CHO, Suwon-si (KR); Seung-Bae PARK, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/211,412

(22) Filed: Sep. 16, 2008

(30) Foreign Application Priority Data
Sep. 18, 2007 (KR) 10-2007-0094723

(51) Int. Cl. G11C 5/02; H01L 21/8242; H01L 27/108

(52) U.S. Cl. 365/51; 438/587; 257/306; 257/E27.084; 257/E21.646

(57) ABSTRACT

A semiconductor device includes an active region in a semiconductor substrate, having first, second and third regions sequentially arranged in the active region. An inactive region in the semiconductor substrate defines the active region. Gate patterns, partially buried in the active and inactive regions, are positioned between the first and second regions or between the second and third regions, intersecting the active region at right angles. A bit line pattern intersects the gate patterns at right angles and overlaps the inactive region, the bit line pattern including a region electrically connected to the second region of the active region. An interlayer insulating layer covers the gate patterns. Storage nodes on the interlayer insulating layer are electrically connected to the active region. A first storage node overlaps the first region and the inactive region and a second storage node overlaps the third region, the inactive region and the bit line pattern.

### PRIORITY CLAIM

A claim of priority is made to Korean Patent Application No. 10-2007-0094723, filed Sep. 18, 2007, in the Korean Intellectual Property Office, the subject matter of which is hereby incorporated by reference.

### BACKGROUND

1. Field

Exemplary embodiments relate to a semiconductor device having storage nodes on active regions and a method of fabricating the same.

2. Description of Related Art

In general, smaller semiconductor devices are being fabricated in accordance with decreasing design rules and increased integration density. A semiconductor device may include an active region, gate patterns, bit line pattern, storage nodes, and the like. The active region may be arranged in a semiconductor substrate in a direction diagonal to the gate patterns or the bit line pattern in order to increase integration density per unit area and decrease size. However, a diagonal arrangement does not take into consideration the alignment system of a semiconductor photolithography apparatus, which moves horizontally and vertically in rows and columns. In other words, it is difficult to accurately align the gate patterns, the bit line pattern, and the storage nodes with the active region. Accordingly, the gate patterns, the bit line pattern, and the storage nodes may not have good electrical characteristics with the active region, and thus deteriorating the semiconductor device.

### SUMMARY

Exemplary embodiments relate to a semiconductor device and method of fabricating the same, and more particularly, to a semiconductor device having storage nodes spaced apart from a bit line pattern on an active region, and a method of fabricating the semiconductor device.

As stated above, exemplary embodiments relate to semiconductor devices having storage nodes, which may be respectively spaced different distances from one side of a bit line pattern in an active region. Also, exemplary embodiments relate to a method of fabricating semiconductor devices having increased area occupied by semiconductor patterns on the active region, even as design rules decrease.

Various embodiments provide a semiconductor device including an active region in a semiconductor substrate, the active region having first, second and third regions sequentially arranged in the active region. An inactive region is in the semiconductor substrate and defines the active region. Multiple gate patterns are partially buried in the active region and the inactive region, each gate pattern being positioned between the first and second regions or between the second and third regions, intersecting the active region at right angles, and passing through the active region and the inactive region. A bit line pattern is on the gate patterns, intersecting the gate patterns at right angles. The bit line pattern overlaps the inactive region and includes a predetermined region electrically connected to the second region of the active region. An interlayer insulating layer covers the gate patterns and surrounds the bit line pattern to expose the bit line pattern. Multiple storage nodes are on the interlayer insulating layer and are electrically connected to the active region. A first storage node overlaps the first region and the inactive region and a second storage node overlaps the third region, the inactive region and the bit line pattern.

The second storage node may be in contact with the bit line pattern on the third region of the active region.

The active region, the gate patterns, the bit line pattern, and the storage nodes may be located at intersections of rows and columns of the semiconductor substrate.

The device may further include multiple neighboring active regions in the semiconductor substrate neighboring the active region. Each neighboring active region may include first, second and third regions sequentially arranged in the corresponding neighboring active region. The first, second and third regions of the active region may respectively face the first, second and third regions of a neighboring active region located in a same row of the semiconductor substrate, and the third region of the active region may face the first region of a neighboring active region located in a same column of the semiconductor substrate.

The gate patterns may be in at least one row of the semiconductor substrate. The bit line pattern may be in a column of the semiconductor substrate. The gate patterns may intersect the bit line pattern at right angles at the respective intersections of the at least one row and the column.

The bit line pattern may be located at least in part in the inactive region between the active region and the neighboring active region located in the same row of the semiconductor substrate. The first storage node may be located at least in part on the active region and partially overlap a bit line pattern adjacent to the active region.

In the intersections among the rows and columns of the semiconductor substrate, storage nodes may be defined between the bit line pattern and the adjacent bit line pattern and arranged diagonally with respect to one another. Also, the storage nodes between the bit line pattern and the adjacent bit line pattern may form a zigzag pattern on the active region with respect to the neighboring active regions.

In the intersections among the rows and columns of the semiconductor substrate, storage nodes of neighboring bit line patterns may be positioned diagonally from one another in different active regions in a first direction, and the storage nodes of the neighboring bit line patterns may be positioned diagonally from one another in twos on each active region in a second direction perpendicular to the first direction.

Various embodiments provide a method of fabricating a semiconductor device, including forming an inactive region in a semiconductor substrate to define an active region, and forming two gate patterns in the active region and the inactive region to intersect the active region at right angles. A first interlayer insulating layer is formed on the active region to cover the gate patterns. A bit line pattern is formed on the first interlayer insulating layer to intersect the gate patterns at right angles, wherein the bit line pattern is formed on the inactive region adjacent to the active region and electrically connected to the active region between the gate patterns through the first interlayer insulating layer. A second interlayer insulating layer is formed on the first interlayer insulating layer to cover the bit line patterns. Storage nodes are formed to overlap the active region adjacent to the gate patterns, the inactive region, and the bit line pattern, and electrically connect to the active region adjacent to the gate patterns through the first and second interlayer insulating layers.

Forming the gate patterns may include forming molding holes corresponding to the gate patterns in the semiconductor substrate; forming a gate insulating layer in the molding holes, forming gates on the gate insulating layer to partially fill the molding holes, and forming gate capping patterns on the gates to fill the molding holes, respectively, and protrude from surfaces of the active region and the inactive region. The gates may be formed of conductive material.

Forming the bit line pattern may include forming a bit line contact hole in the first interlayer insulating layer to expose the active region between the gate patterns, forming a bit line contact to fill the bit line contact hole, forming a bit line conductive layer and a bit line capping layer to cover the bit line contact, and sequentially etching the bit line capping layer and the bit line conductive layer until the first interlayer insulating layer is exposed. The bit line contact may be formed of conductive material, and a predetermined region of the bit line pattern may be in contact with the bit line contact.

Electrically connecting the storage nodes to the active region adjacent to the gate patterns may include forming node contact holes in the first and second interlayer insulating layers to expose the active region adjacent to the gate patterns, the bit line contact hole being formed between the node contact holes; forming node contacts using conductive material to fill the node contact holes; and forming the storage nodes on the node contacts, respectively. The bit line contact hole may be formed between the node contact holes.

One of the storage nodes may be in contact with the bit line pattern, and one of the node contacts. Also, the active region, the gate patterns, the bit line pattern, the node contacts, and the storage nodes may be located at intersections of rows and columns of the semiconductor substrate.

Neighboring active regions adjacent to the active region in a select row of the semiconductor substrate may be formed in a horizontal direction to have the same center and area as the active region. Neighboring active regions adjacent to the active region in a select column of the semiconductor substrate may be formed in a vertical direction to have the same center and area as the active region.

In the intersections of the rows and columns of the semiconductor substrate, the gate patterns may be formed in at least one row of the semiconductor substrate, the bit line pattern may be formed in a column of the semiconductor substrate. The gate patterns may intersect the bit line pattern at right angles at the respective intersections.

In the intersections of the rows and columns of the semiconductor substrate, the bit line pattern may be formed in the inactive region between two neighboring active regions in the select row of the semiconductor substrate.

In the intersections of the rows and columns of the semiconductor substrate, the storage nodes may be formed on a select active region to partially overlap two neighboring bit line patterns adjacent to the select active region.

In the intersections of the rows and columns of the semiconductor substrate, the storage nodes may be defined between the bit line pattern and a neighboring bit line pattern adjacent to the select active region and formed to face each other in a diagonal direction. Also, the storage nodes and storage nodes of the neighboring bit line pattern may be formed in a zigzag pattern on the active regions.

In the intersections of the rows and columns of the semiconductor substrate, the storage nodes and storage nodes of two neighboring bit line patterns may be diagonally formed on different active regions from one another in a first direction. The storage nodes of each bit line pattern may be diagonally formed in twos on each of the corresponding different active regions from one another in a second direction perpendicular to the first direction.

### BRIEF DESCRIPTION OF THE DRAWINGS

The embodiments of the present invention will be described with reference to the attached drawings. The drawings are not necessarily to scale, emphasis instead being placed upon illustrating the principles of the example embodiments.

FIG. 1 is a plan view showing a semiconductor device, according to exemplary embodiments.

FIGS. 2A, 2B and 2C are cross-sectional views taken along lines I-I′, II-II′, and III-III′ of FIG. 1, respectively, according to exemplary embodiments.

FIGS. 3A, 4A, 5A, 6A, 7A, 8A and 9A are cross-sectional views taken along line I-I′ of FIG. 1, which illustrate a method of fabricating the semiconductor device shown in FIG. 1, according to exemplary embodiments.

FIGS. 3B, 4B, 5B, 6B, 7B, 8B and 9B are cross-sectional views taken along line II-II′ of FIG. 1, which illustrate the method of fabricating the semiconductor device shown in FIG. 1, according to exemplary embodiments.

FIGS. 3C, 4C, 5C, 6C, 7C, 8C and 9C are cross-sectional views taken along line III-III′ of FIG. 1, which illustrate the method of fabricating the semiconductor device shown in FIG. 1, according to exemplary embodiments.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

It will be understood that although the terms first and second are used herein to describe various members, devices, regions, layers, and/or sections, the members, devices, regions, layers and/or sections should not be limited by these terms. These terms are used to distinguish one member, device, region, layer or section from another member, device, region, layer or section. As used herein, “rows and columns” may be used to describe a two-dimensional arrangement of semiconductor patterns on a semiconductor substrate. Also, the term “and/or” includes any and all combinations of one or more of the associated listed items. Spatially relative terms, such as “upper”, “lower”, “adjacent”, “corresponding”, “partially”, “portion”, “remaining”, “opposite”, and “on” and the like, may be used for ease of description to describe one element or feature's relationship to another element(s) or feature(s), as illustrated in the figures. The terminology used herein is for the purpose of describing particular embodiments only and is not intended to be limiting of the embodiments.

A semiconductor device having storage nodes respectively spaced different distances from one side of a bit line pattern on a particular active region, according to illustrative embodiments, will be described more fully herein with reference to the accompanying drawings, in which illustrative embodiments are shown.

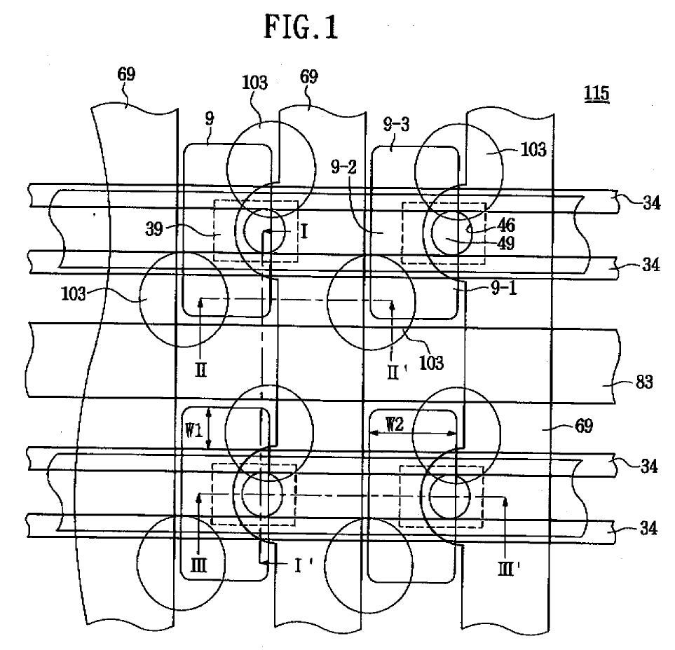

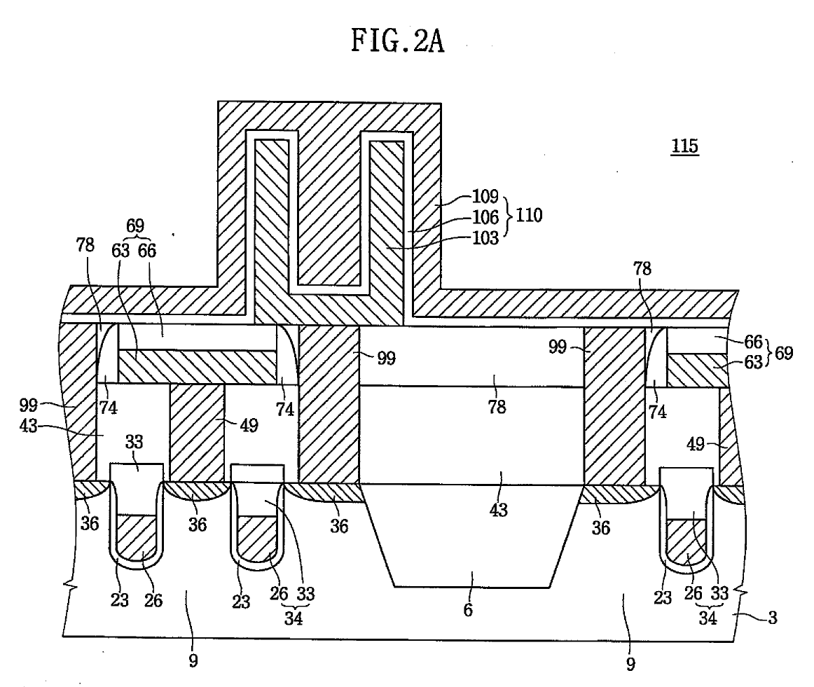

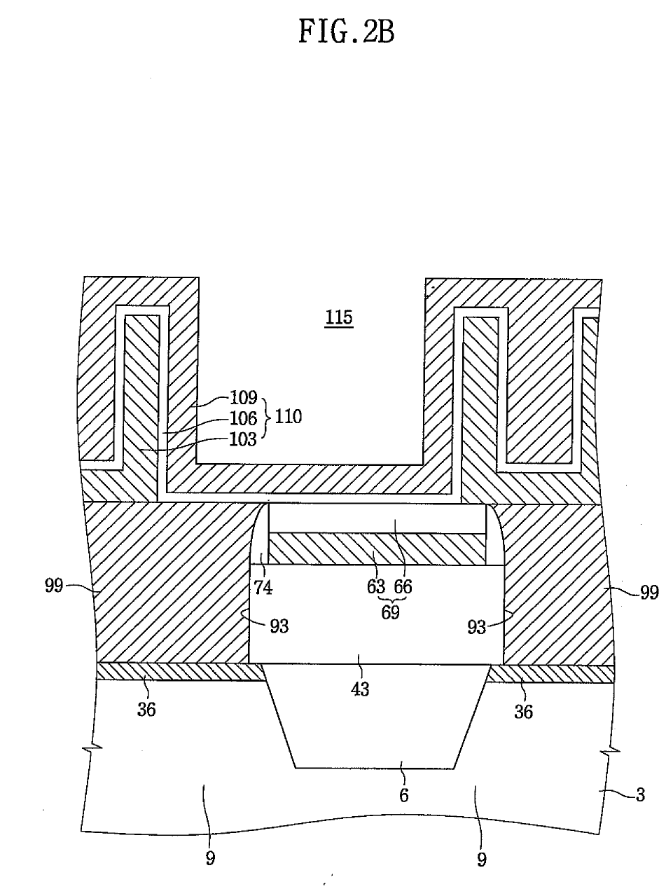

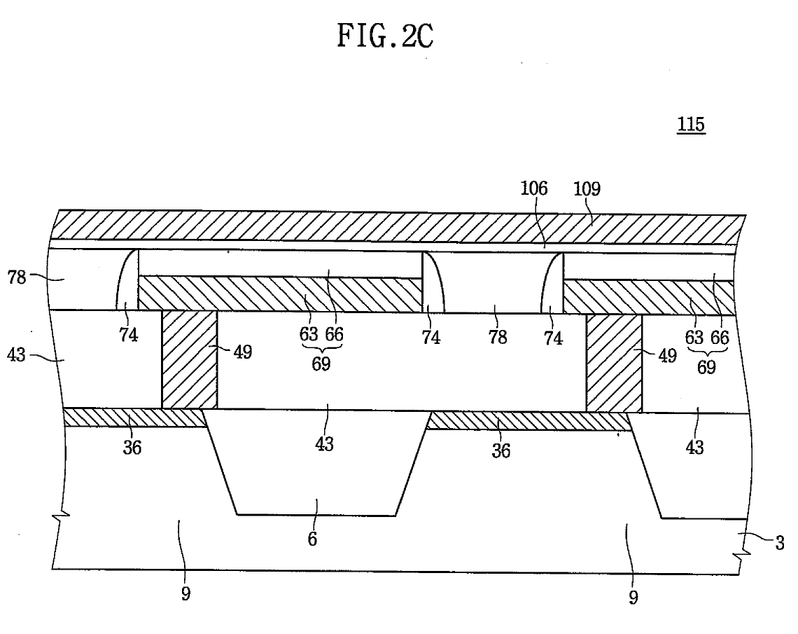

FIG. 1 is a plan view showing a semiconductor device, according to illustrative embodiments. FIGS. 2A through 2C are cross-sectional views taken along lines I-I′, II-II′, and III-III′ of FIG. 1, respectively.

Referring to FIGS. 1 and 2A through 2C, a semiconductor device 115 includes gate patterns 34, which are positioned in rows on a semiconductor substrate 3, as shown in FIGS. 1 and 2A. For example, two neighboring gate patterns 34 may be arranged to correspond to a select row of the semiconductor substrate 3, as shown in FIG. 1. Also, each of the gate patterns 34 may include a gate 26 and a gate capping pattern 33, as shown in FIG. 2A. Bit line patterns 69 are located on the gate patterns 34 as shown in FIGS. 1 and 2A through 2C. The bit line patterns 69 may be arranged in columns on the semiconductor substrate 3, as shown in FIG. 1. The bit line patterns 69 may intersect the gate patterns 34 at right angles at intersections between the rows and the columns of the semiconductor substrate 3. Each of the bit line patterns 69 may include a bit line 63 and a bit line capping pattern 66, as shown in FIGS. 2A through 2C. The gate 26 and the bit line 63 may be formed of conductive material, and the gate capping pattern 33 and the bit line capping pattern 66 may be formed of insulating material, for example.

In illustrative embodiments, active regions 9 are located under the gate patterns 34 and the bit line patterns 69, as shown in FIGS. 1 and 2A through 2C. The active regions 9 may respectively correspond to the intersections between the rows and columns of the semiconductor substrate 3, as shown in FIG. 1. The active regions 9 may be located between neighboring bit line patterns 69. Each of the active regions 9 may be formed to have first through third regions 9-1, 9-2, and 9-3, which are sequentially arranged from one side of the gate patterns 34 to the other side. According to various embodiments, the first through third regions 9-1, 9-2 and 9-3 of two neighboring active regions 9 with respect to a particular row of the semiconductor substrate 3 may face each other, that is, they may be aligned across from one another, respectively. Also, first and third regions 9-1 and 9-3 of two neighboring active regions 9 with respect to a select column of the semiconductor substrate 3 may face each other. The active regions 9 may be defined by an inactive region 6, as shown in FIGS. 2A through 2C. The inactive region 6 may include a device isolating layer, for example. The bit line patterns 69 may be located in the inactive region 6, as shown in FIG. 2B.

The active regions 9 may to correspond to the two neighboring gate patterns 34, for example, of a select row of the semiconductor substrate 3, as shown in FIG. 1. More specifically, one of the two neighboring gate patterns 34 may be positioned between the first and second regions 9-1 and 9-2 of a particular active region 9, and the other gate pattern 34 may be positioned between the second and third regions 9-2 and 9-3 of the same active region 9. The gate patterns 34 may be arranged in the active regions 9 and the inactive region 6 as shown in FIGS. 1 and 2A. The gate 26 of each of the gate patterns 34 may be buried in the active regions 9 and the inactive region 6. The gate capping pattern 33 of each of the gate patterns 34 may be located on the corresponding gate 26 and protrude from the respective surfaces of the inactive region 6 and the active regions 9, as shown in FIG. 2A. An interlayer insulating layer or inter-gate dielectric layer 43 may be on the inactive region 6 and the active regions 9 to cover the gate patterns 34 as shown in FIGS. 2A through 2C.

Referring again to FIGS. 1 and 2A through 2C, bit line contacts 49 are located in the inter-gate dielectric layer 43, as shown in FIGS. 2A through 2C. The bit line contacts 49 are exposed by the inter-gate dielectric layer 43. Each of the bit line contacts 49 may contact the second region 9-2 of the particular active region 9 between two neighboring gate patterns 34, as shown in FIGS. 1, 2A and 2C. The bit line contacts 49 may be formed of conductive material, for example. The bit line contacts 49 may be in contact with the bit line patterns 69, as shown in FIGS. 2A and 2C. More specifically, a predetermined region of each of the bit line patterns 69 may extend from the inactive region 6 toward the active region 9 and contact the bit line contacts 49, as shown in FIGS. 1 and 2C. A bit line interlayer insulating layer 78 may be disposed on the inter-gate dielectric layer 43 to cover the bit line patterns 69, as shown in FIGS. 2A through 2C. The bit line interlayer insulating layer 78 may expose the bit line patterns 69. Node contacts 99 may be located in the inter-gate dielectric layer 43 and the bit line interlayer insulating layer 78, as shown in FIGS. 2A through 2C. Upper portions of the node contacts 99 may be exposed by the bit line interlayer insulating layer 78. The node contacts 99 may be in contact with the active regions 9. The node contacts 99 may be formed of conductive material, for example.

The node contacts 99 in the particular active region 9 may be positioned diagonally across from one another in the first and third regions 9-1 and 9-3, e.g., facing each other in a diagonal direction, as indicated by the locations of corresponding storage nodes 103 shown in FIG. 1. More particularly, the storage nodes 103 are located on the node contacts 99, as shown in FIGS. 1, 2A, and 2B, and are in contact with the node contacts 99. The storage nodes 103 may be formed of conductive material, for example. One storage node 103 in the particular active region 9 may overlap the first region 9-1 and the inactive region 6 adjacent to the first region 9-1, and simultaneously the other storage node 103 may overlap the third region 9-3 and the inactive region 6 adjacent to the third region 9-3. The storage nodes 103 in the particular active region 9 may contact the bit line patterns 69 adjacent to the active region 9, as shown in FIGS. 2A and 2B.

The storage nodes 103 in the particular active region 9 may be defined between two neighboring bit lines patterns 69 adjacent to the particular active region 9 and positioned diagonally across the active region 9, thus facing each other in a diagonal direction, as shown in FIG. 1. Accordingly, the storage nodes 103 between the two neighboring bit line patterns 69 may be arranged in a zigzag pattern on the active regions 9, as shown in FIG. 1. Thus, the storage nodes 103 are spaced differently from one side of each bit line pattern 69. Storage nodes 103 of three neighboring bit line patterns 69 may be diagonally arranged on different active regions 9 from one another in a first direction, as shown in FIG. 1. Also, the storage nodes 103 of the three neighboring bit line patterns 69 may be diagonally arranged with respect to one another in sets of two on each of the different active regions 9 in a second direction perpendicular to the first direction, as shown in FIG. 1.

Referring again to FIGS. 2A through 2C, a dielectric layer 106 and a plate 109 may be located on the bit line interlayer insulating layer 78 to cover the bit line patterns 69, the node contacts 99, and the storage nodes 103. The dielectric layer 106 may be formed of silicon oxide, silicon nitride, metal oxide, or combination thereof, for example. The plate 109 may be formed of conductive material, for example. Each of the storage nodes 103 may correspond to a lower electrode of a capacitor, and the plate 109 may correspond to an upper electrode of the capacitor. Meanwhile, bit line spacers 74, formed of an insulating material, for example, may be included on sidewalls of the bit line patterns 69. Also, impurity diffusion regions 36 may be formed in the active regions 9. The impurity diffusion regions 36 may be located between the gate patterns 34 and contacted by the bit line contacts 49 and the node contacts 99, respectively. The impurity diffusion regions 36 may have a different conductivity type than the semiconductor substrate 3, for example.

Methods of fabricating a semiconductor device having storage nodes respectively spaced different distances apart from one side of a bit line pattern in an active region, according to illustrative embodiments, will now be described with reference to FIGS. 1, 3A to 9A, 3B to 9B, and 3C to 9C.

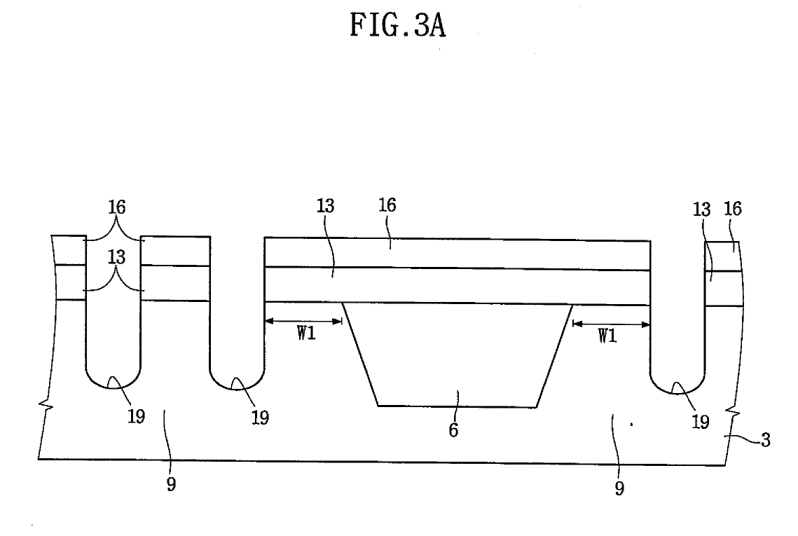

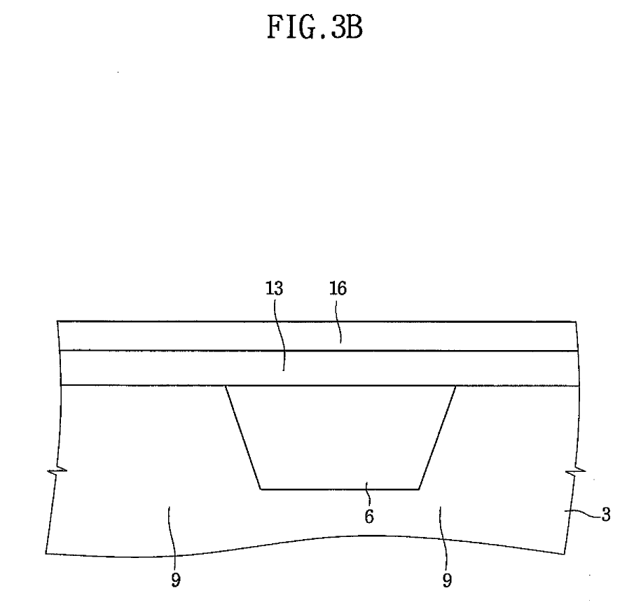

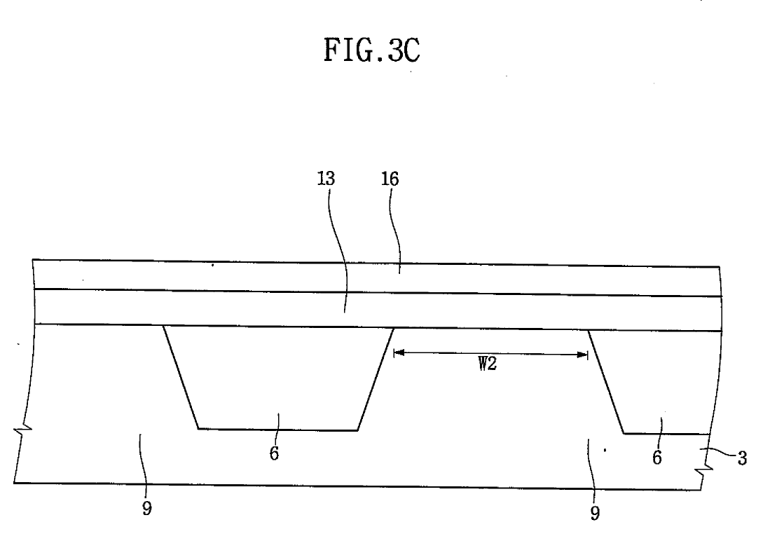

FIGS. 3A, 4A, 5A, 6A, 7A, 8A and 9A are cross-sectional views taken along line I-I′ of FIG. 1. FIGS. 3B, 4B, 5B, 6B, 7B, 8B and 9B are cross-sectional views taken along line II-II′ of FIG. 1. FIGS. 3C, 4C, 5C, 6C, 7C, 8C and 9C are cross-sectional views taken along line III-III′ of FIG. 1. FIGS. 3A, 4A, 5A, 6A, 7A, 8A, 9A, 3B, 4B, 5B, 6B, 7B, 8B and 9B, 3C, 4C, 5C, 6C, 7C, 8C and 9C illustrate a method of fabricating the semiconductor device shown in FIG. 1, according to illustrative embodiments.

Referring to FIGS. 1 and 3A through 3C, an inactive region 6 is formed in a semiconductor substrate 3, as shown in FIGS. 3A through 3C. The inactive region 6 may be filled with a device isolating layer, which may be formed using at least one insulating layer. The inactive region 6 defines active regions 9. The active regions 9 are formed in rows and columns of the semiconductor substrate 3, as shown in FIG. 1. More specifically, active regions 9 in a select row of the semiconductor substrate 3 may be sequentially formed in a horizontal direction to have the same center and area. Active regions 9 in a select column in the semiconductor substrate 3 may be sequentially formed in a vertical direction to have the same center and area. A pad base layer 13 and a pad mask layer 16 are formed on the inactive region 6 to cover the active regions 9, as shown in FIGS. 3A through 3C. The pad base layer 13 and the pad mask layer 16 may be formed of insulating materials respectively having different etch rates, for example.

Molding holes 19 are formed in the inactive region 6 and the active regions 9 through the pad base layer 13 and the pad mask layer 16, as shown in FIG. 3A. The molding holes 19 may be formed to be vertical to the active regions 9 in rows of the semiconductor substrate 3. Since the molding holes 19 are aligned vertically with respect to the active regions 9, the molding holes 19 may be accurately aligned with the active regions 9 even in an unstable semiconductor fabrication process, compared to a conventional art in which molding holes are aligned diagonally with respect to active regions. The molding holes 19 may extend from surfaces of the inactive region 6 and the active regions 9 toward a lower portion of the semiconductor substrate 3. Although not shown in FIGS. 3A through 3C, the molding holes 19 may extend to the inactive region 6 through the active regions 9. Each of the active regions 9 may have a predetermined width W1 between a molding hole 19 and the inactive region 6 in a select column of the semiconductor substrate 3, as shown in FIGS. 1 and 3A. Also, each of the active regions 9 may have a predetermined width W2 in a select row of the semiconductor substrate 3 and be surrounded by the inactive region 6, as shown in FIGS. 1 and 3C.

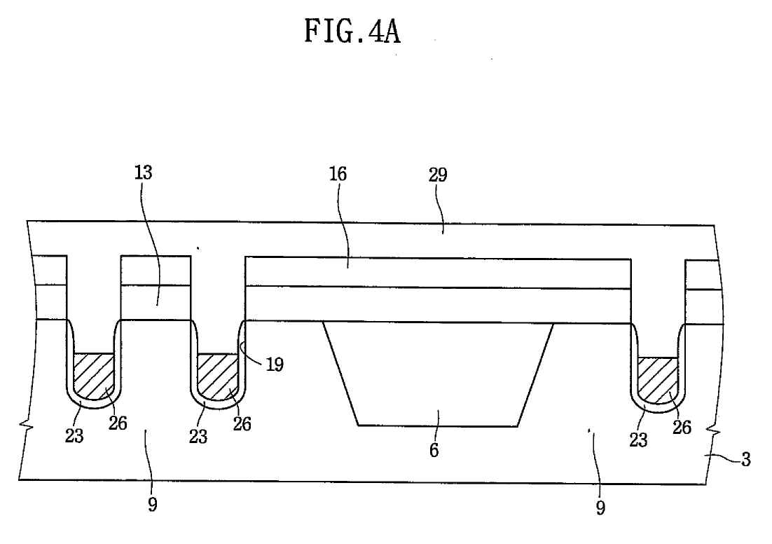

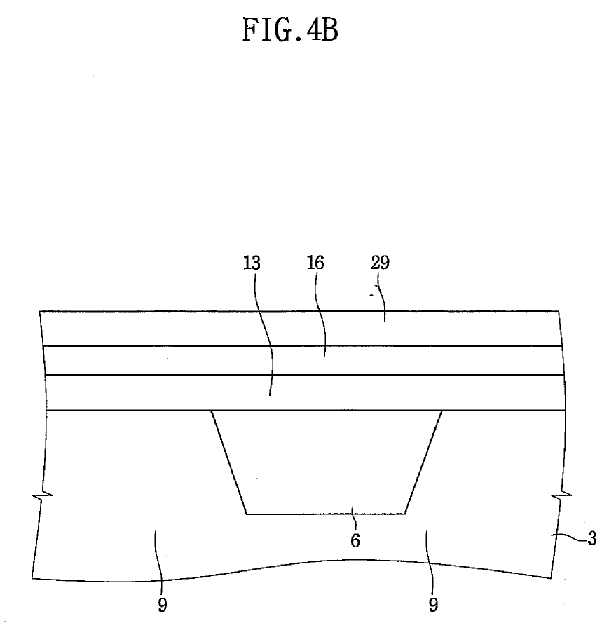

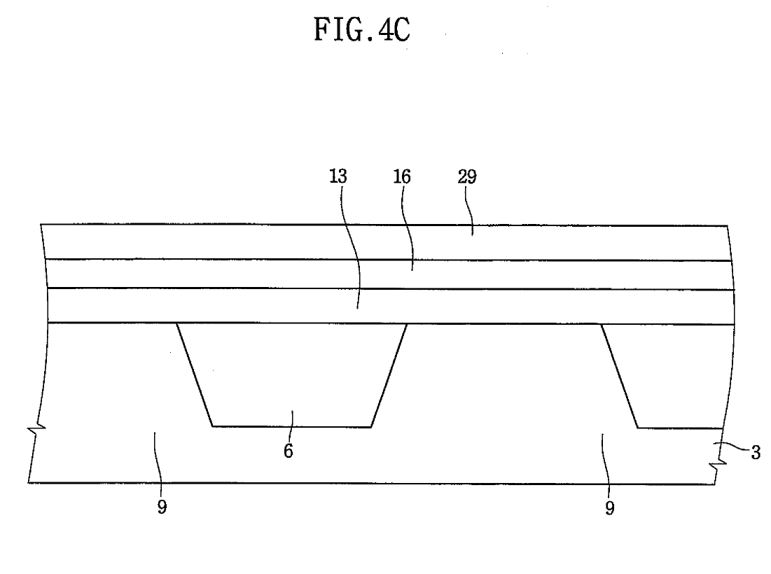

Referring to FIGS. 1 and 4A through 4C, a gate insulating layer 23 is formed in the molding holes 19 using the pad base layer 13 and the pad mask layer 16 as a mask, as shown in FIG. 4A. The gate insulating layer 23 may be formed of silicon oxide, silicon oxynitride, or metal oxide, for example. Gates 26 are formed on the gate insulating layer 23 to partially fill the respective molding holes 19, as shown in FIG. 4A. The gates 26 may be formed of metal nitride, for example. A gate capping layer 29 is formed on the gates 26 to cover the pad base layer 13 and the pad mask layer 16, as shown in FIGS. 4A through 4C. The gate capping layer 29 may be formed of insulating material having the same etch rate as the pad mask layer 16, for example.

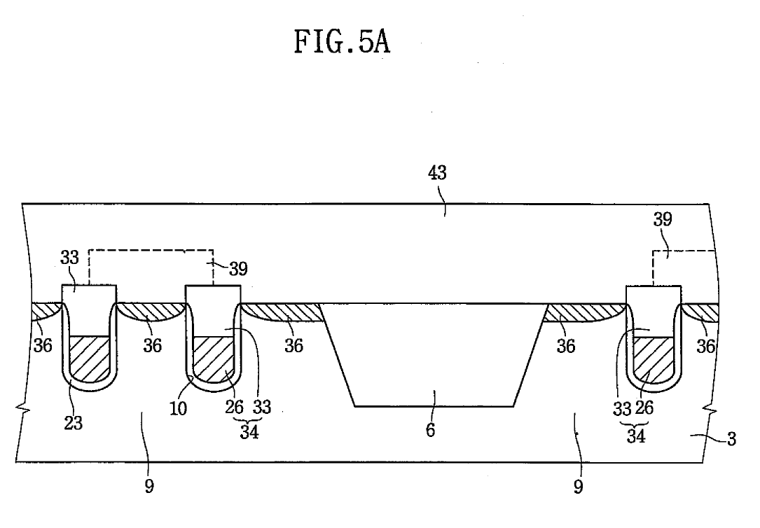

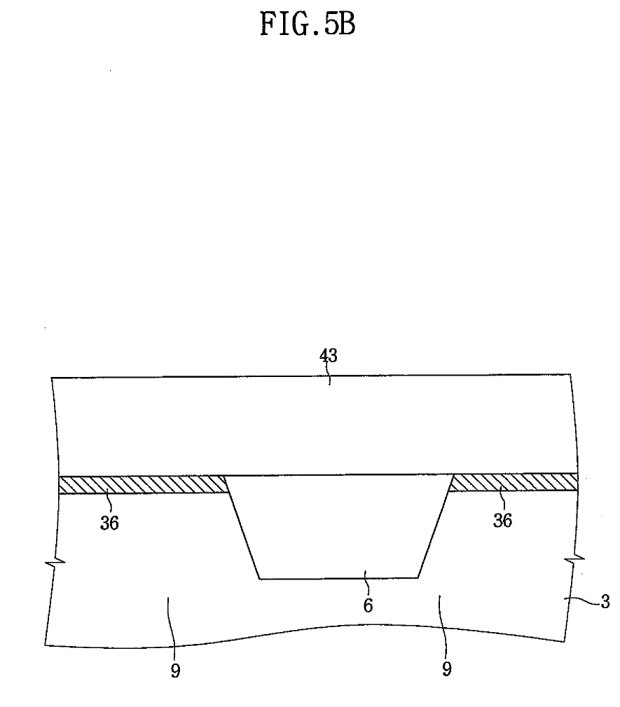

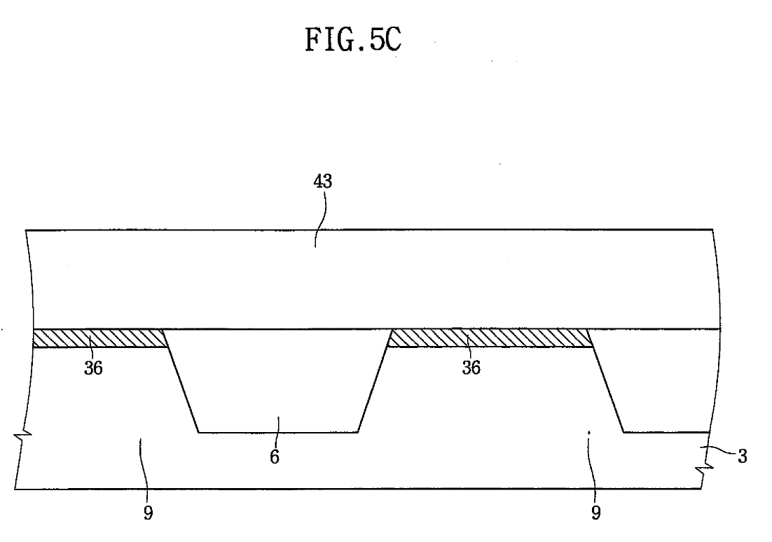

Referring to FIGS. 1 and 5A through 5C, a chemical mechanical polishing (CMP) process may be performed on the gate capping layer 29 and the pad mask layer 16 using the pad base layer 13 as an etch buffer layer, thereby forming gate capping patterns 33, as shown in FIG. 5A. The gate capping patterns 33 are formed on the gates 26. The gate capping patterns 33 may be filled in the molding holes 19 and protrude from surfaces of the active regions 9 and the inactive region 6. The CMP process may be replaced by another process, such as an etch-back process, for example. Subsequently, the pad base layer 13 is removed using the gate capping patterns 33 as an etch buffer layer until the semiconductor substrate 3 is exposed, as shown in FIGS. 5A through 5C. As a result, the gates 26 and the gate capping patterns 33 may form gate patterns 34, which are defined by the molding holes 19, as shown in FIGS. 1 and 5A.

Since the gate patterns 34 are defined by the molding holes 19, the gate patterns 34 may be formed at right angles to the active regions 9 in rows of the semiconductor substrate 3. Two neighboring gate patterns 34 adjacent to a particular row of the semiconductor substrate 3 may correspond to one of the active regions 9, as shown in FIGS. 1 and 5A. Impurity diffusion regions 36 may be formed in the active regions 9 using the gate patterns 34 and the inactive region 6 as a mask. The impurity diffusion regions 36 may be formed between the gate patterns 34 and between a gate pattern 34 and the inactive region 6. The impurity diffusion regions 36 may have a different conductivity type than the semiconductor substrate 3. In illustrative embodiments, landing pads 39 may be formed in central regions of the active regions 9 between the gate patterns 34 along rows of the semiconductor substrate 3, as shown in FIGS. 1 and 5A. The landing pads 39 may be formed of conductive material, for example. An interlayer insulating layer or inter-gate dielectric layer 43 may be formed on the active regions 9 and the inactive region 6 to cover the gate patterns 34, as shown in FIGS. 5A through 5C. The inter-gate dielectric layer 43 may have a different etch rate than the gate capping patterns 33 and the landing pads 39.

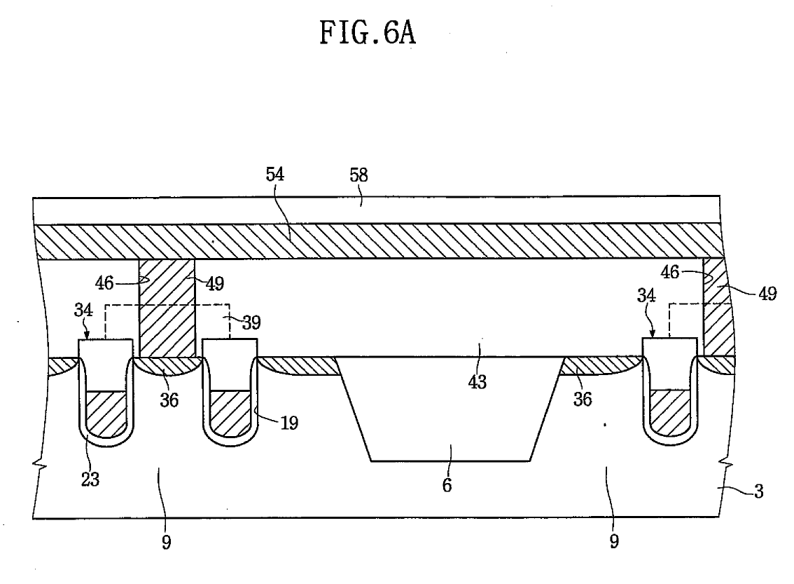

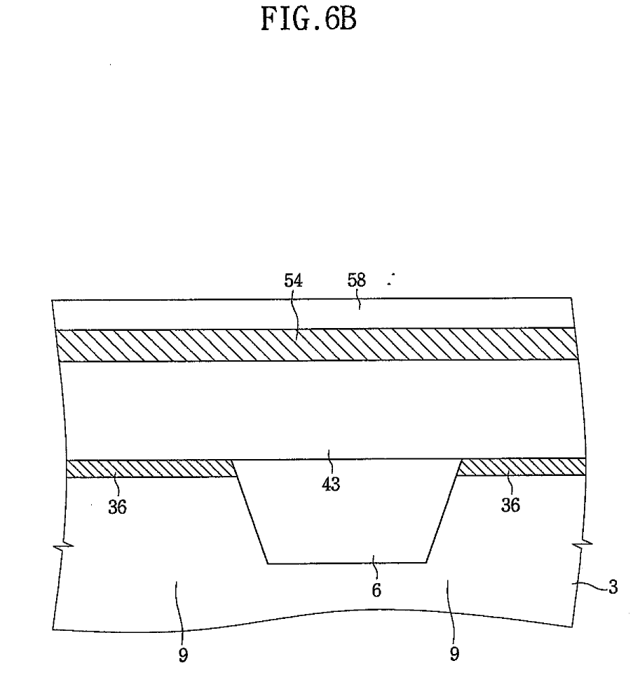

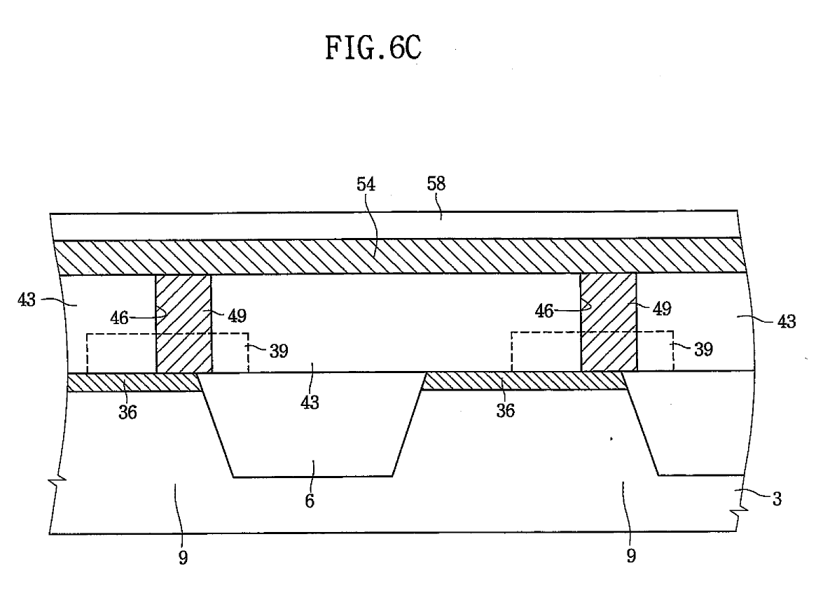

Referring to FIGS. 1 and 6A through 6C, bit line contact holes 46 are formed in the inter-gate dielectric layer 43, as shown in FIGS. 6A and 6C. The bit line contact holes 46 may be formed in the central regions of the active regions 9 between the gate patterns 34 along the rows of the semiconductor substrate 3 as shown in FIG. 1. The bit line contact holes 46 may expose the active regions 9. In the case that the landing pads 39 are formed as shown in FIG. 5A, the bit line contact holes 46 may be formed on the respective landing pads 39. Bit line contacts 49 may be formed in the bit line contact holes 46, as shown in FIGS. 1 and 6A through 6C. The bit line contacts 49 may be in contact with the impurity diffusion regions 36, respectively. The bit line contacts 49 may be formed of conductive material, for example. A bit line conductive layer 54 and a bit line capping layer 58 may be sequentially formed on the inter-gate dielectric layer 43 to cover the bit line contacts 49, as shown in FIGS. 6A through 6C. The bit line conductive layer 54 may be formed of conductive material. The bit line capping layer 58 may be formed of insulating material, for example, having the same etch rate as the gate capping pattern 34.

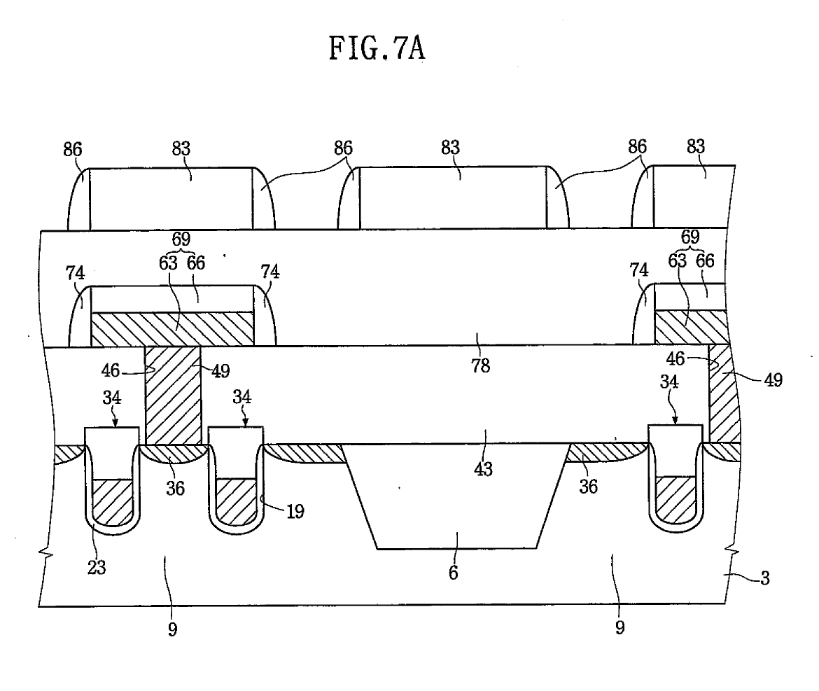

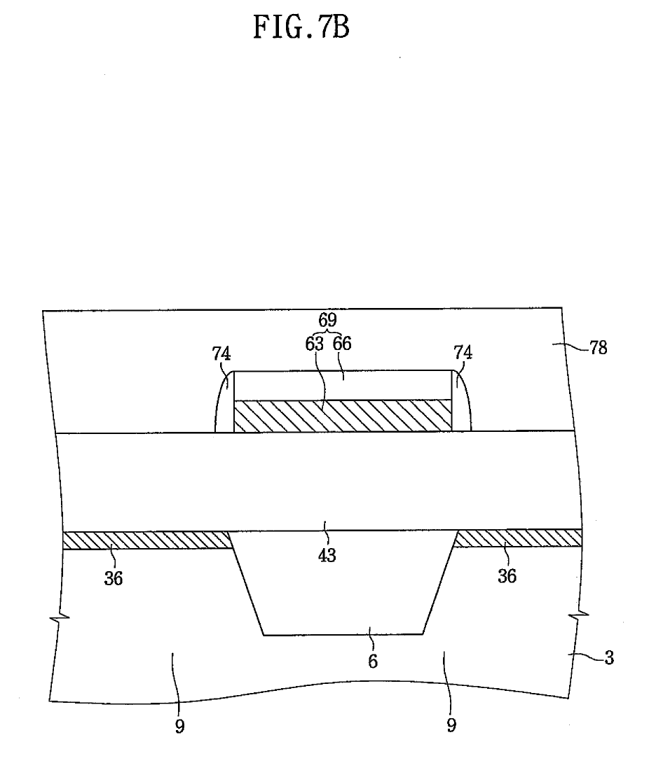

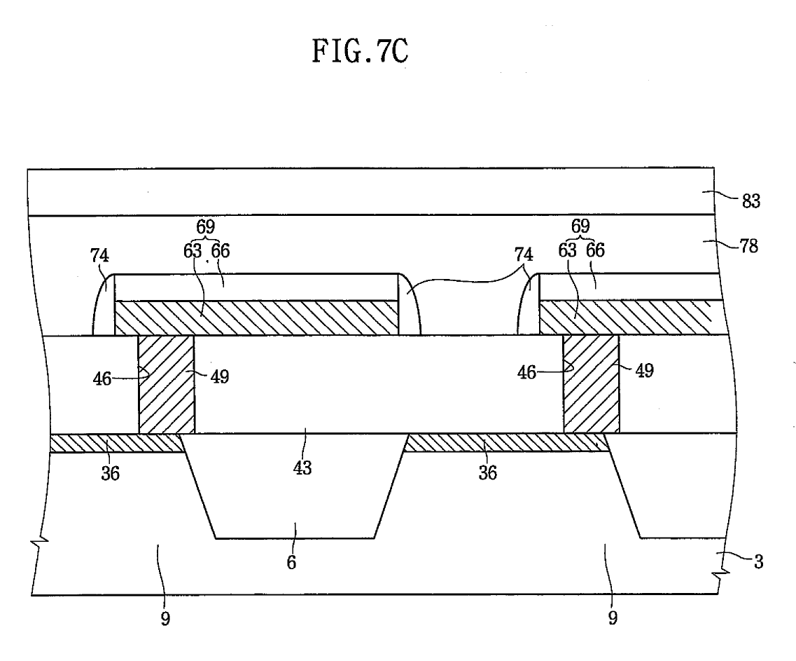

Referring to FIGS. 1 and 7A through 7C, the bit line capping layer 58 and the bit line conductive layer 54 are sequentially etched until the inter-gate dielectric layer 43 is exposed, thereby forming bit line patterns 69, as shown in FIGS. 7A through 7C. Each of the bit line patterns 69 may include a bit line 63 and a bit line capping pattern 66. The bit line patterns 69 may intersect the gate patterns 34 at right angles at intersections among the rows and columns of the semiconductor substrate 3, as shown in FIG. 1. The bit line patterns 69 may be formed on the inactive region 6 between the active regions 9 along the columns of the semiconductor substrate 3. Since the bit line patterns 69 are located on the inactive region 6 and aligned parallel to the active regions 9, the bit line patterns 69 may expose the active regions 9 more effectively, even in an unstable semiconductor fabrication process, compared to the conventional art in which bit line patterns are aligned diagonally to active regions. In a particular column of the semiconductor substrate 3, predetermined regions of the bit line patterns 69 may extend from the inactive region 6 toward the active regions 9, as shown in FIGS. 1 and 7C. Bit line spacers 74 may be formed on sidewalls of the bit line patterns 69, as shown in FIGS. 7A through 7C. The bit line spacers 74 may be formed of insulating material, for example, having the same etch rate as the bit line capping patterns 66.

A bit line interlayer insulating layer 78 may be formed on the inter-gate dielectric layer 43 to cover the bit line patterns 69 and the bit line spacers 74, as shown in FIGS. 7A through 7C. The bit line interlayer insulating layer 78 may have the same etch rate as the inter-gate dielectric layer 43, for example. Node mask patterns 83 may be formed on the bit line interlayer insulating layer 78, as shown in FIGS. 7A and 7C. The node mask patterns 83 may be formed of insulating material, for example, having a different etch rate than the bit line interlayer insulating layer 78. The node mask patterns 83 may be formed along the rows of the semiconductor substrate 3. Portions of the node mask patterns 83 may be formed along the gate patterns 34 and overlap the gate patterns 34, as shown in FIGS. 1 and 7A. The remaining node mask patterns 83 may be formed on the inactive region 6 between the gate patterns 34, as shown in FIGS. 1 and 7A. Mask spacers 86 may be formed on sidewalls of the node mask patterns 83, as shown in FIG. 7A. The mask spacers 86 may be formed of insulating material, for example, having the same etch rate as the bit line capping patterns 66.

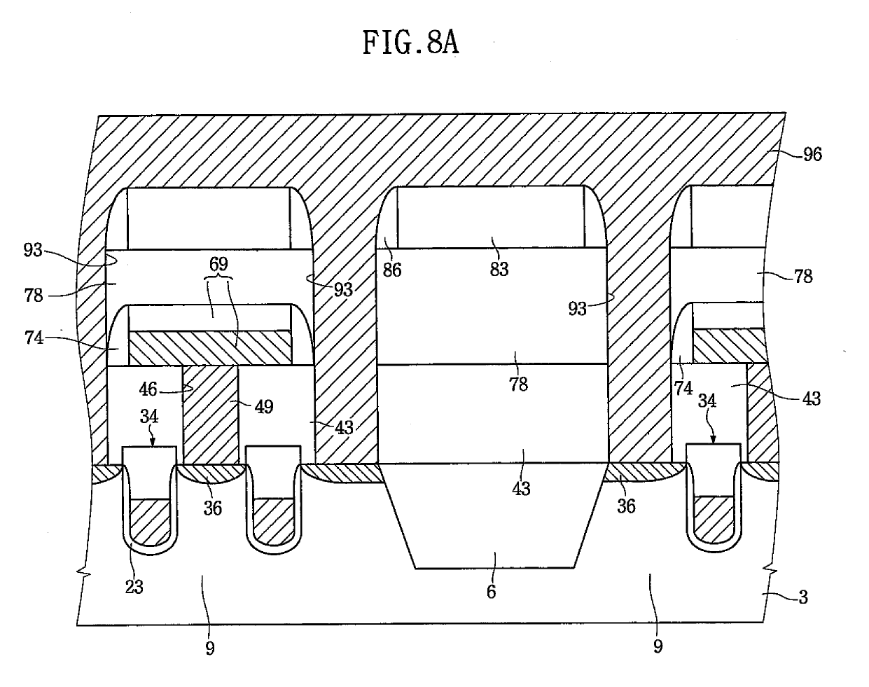

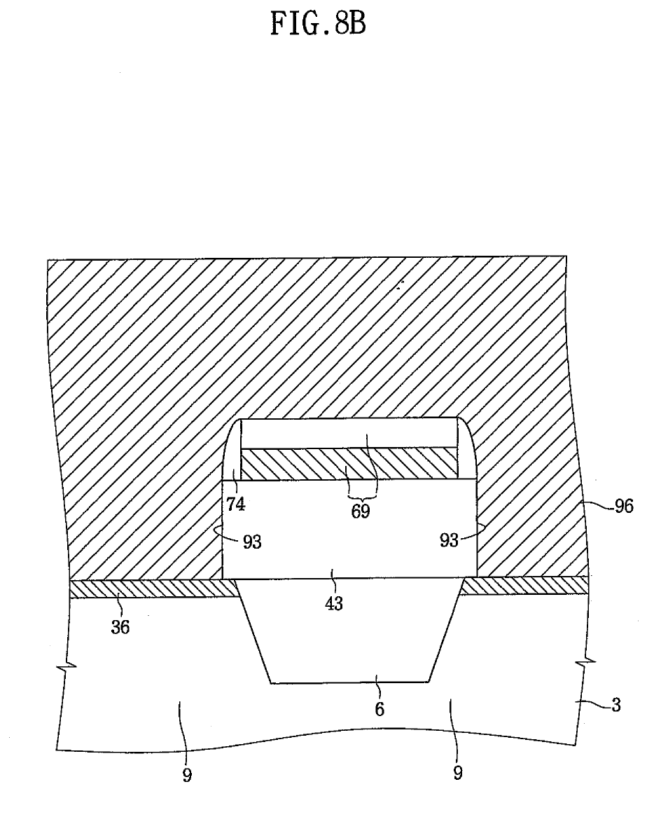

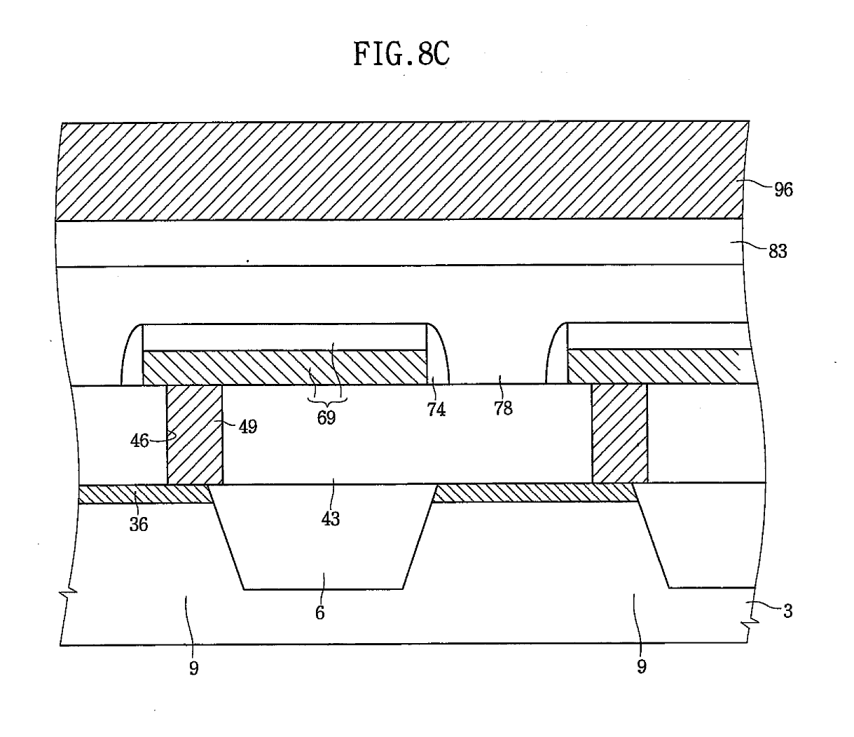

Referring to FIGS. 1 and 8A through 8C, the bit line interlayer insulating layer 78 and the inter-gate dielectric layer 43 may be sequentially etched using the bit line patterns 69, the bit line spacers 74, the node mask patterns 83, and the mask spacers 86 as an etch mask, thereby forming node contact holes 93, as shown in FIGS. 8A and 8B. In this case, the node contact holes 93 may be formed in twos on each of the active regions 9, as shown in FIGS. 1, 8A, and 8B. More specifically, two neighboring node contact holes 93 may be arranged diagonally from one another on a particular active region 9, thus facing each other in a diagonal direction. The node contact holes 93 may expose the active regions 9, the bit line patterns 69 and the bit line spacers 74, as shown in FIGS. 8A and 8B. A node contact layer 96 may be formed to fill the node contact holes 93 and cover the node mask patterns 83 as shown in FIGS. 8A through 8C. The node contact layer 96 may be formed of conductive material, for example.

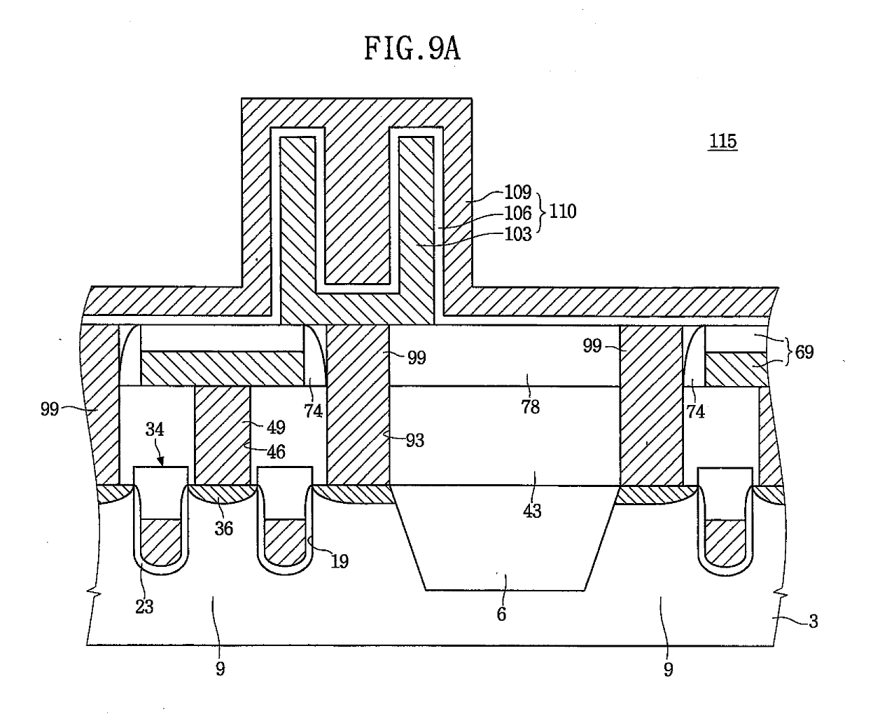

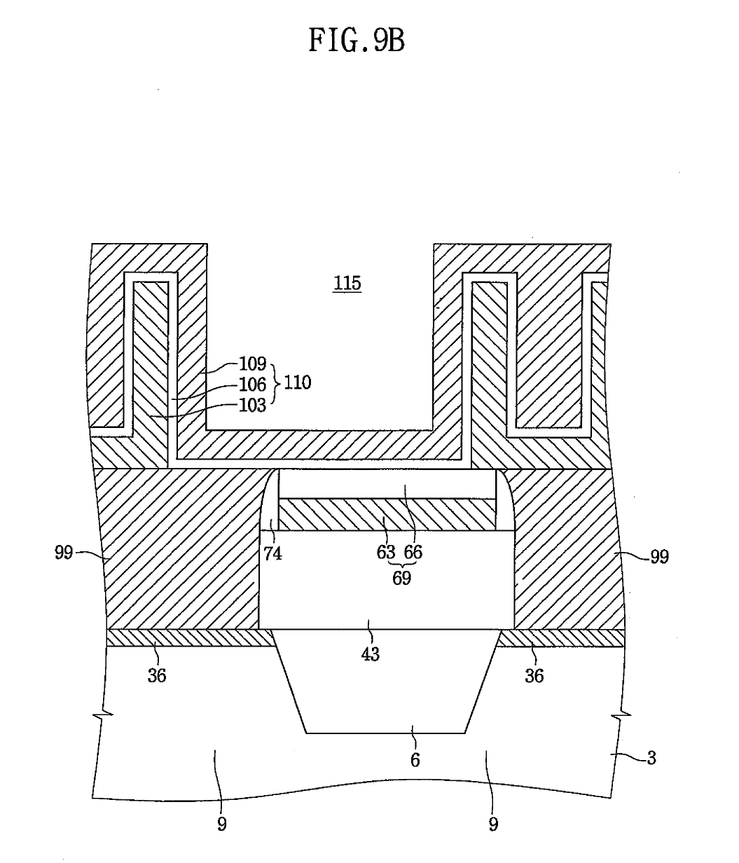

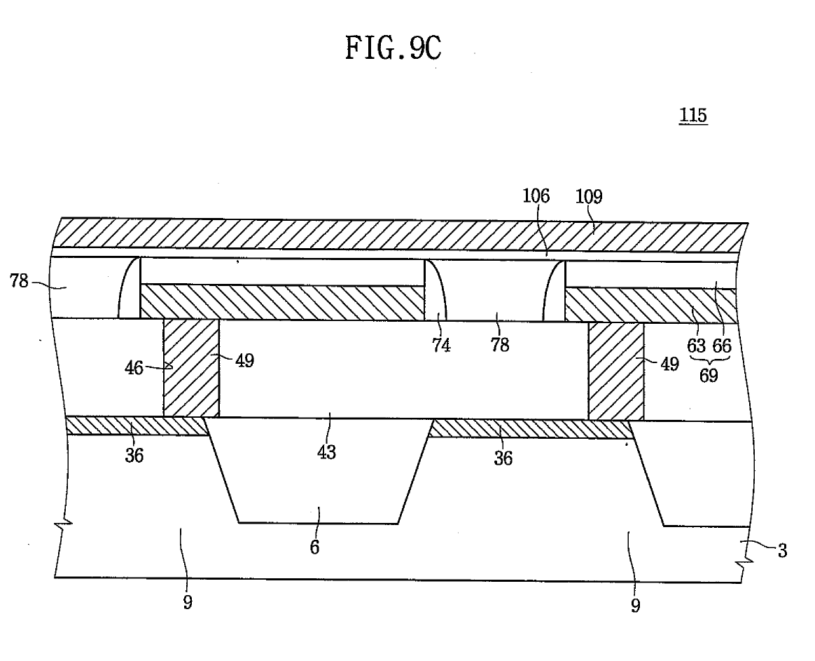

Referring to FIGS. 1 and 9A through 9C, a CMP process is performed on the node mask patterns 83, the mask spacers 86, and the bit line interlayer insulating layer 78 using the bit line patterns 69 and the bit line spacers 74 as an etch buffer layer. As a result, node contacts 99 may be formed in the respective node contact holes 93 as shown in FIGS. 9A and 9B. The node contacts 99 may traverse the sidewalls of the bit line contacts 49 to be in contact with the impurity diffusion regions 36. Storage nodes 103 may be formed on the node contacts 99 as shown in FIGS. 1, 9A, and 9B. Since the storage nodes 103 are aligned with the active regions 9 disposed parallel to the bit line patterns 69, the storage nodes 103 may be desirably aligned with the active regions 9 even in the unstable semiconductor fabrication process, as compared to a conventional process in which storage nodes are aligned with active regions arranged diagonally to bit line patterns. The storage nodes 103 may be formed of conductive material, for example. The storage nodes 103 may overlap the inactive region 6, the active regions 9, and the bit line patterns 69 as shown in FIGS. 1, 9A and 9B. Portions of storage nodes 103 in a particular active region 9 may be in contact with bit line patterns 69 neighboring the active region 9, as shown in FIGS. 1, 9A and 9B.

The storage nodes 103 located on a particular active region 9 may be defined between the bit line patterns 69 adjacent to the active region 9 and arranged diagonally across the active region 9, thus facing each other in a diagonal direction, as shown in FIG. 1. Storage nodes 103 between two neighboring bit line patterns 69 may be formed in a zigzag pattern on the active regions 9. Storage nodes 103 neighboring among three neighboring bit line patterns 69 may be diagonally arranged with respect to one another on different active regions 9 in a first direction as shown in FIG. 1. Also, the storage nodes 103 among the three neighboring bit line patterns 69 may be diagonally arranged with respect to one another in twos on each of the active regions 9 in a second direction perpendicular to the first direction, as shown in FIG. 1. Since the storage nodes 103 partially overlap the active regions 9 adjacent to the gate patterns 69, a process margin by which the storage nodes 103 can desirably overlap the active regions 9 can be increased, regardless of decreases in design rules.

Subsequently, a dielectric layer 106 and a plate 109 may be formed on the bit line patterns 69, the bit line interlayer insulating layer 78, and the node contacts 99 to cover the storage nodes 103. The dielectric layer 106 may be formed of silicon oxide, silicon nitride, metal oxide, or combination thereof, for example. The plate 109 may be formed of conductive material, for example. The dielectric layer 106 and the plate 109 may constitute capacitors along with the storage nodes 103. The capacitors, along with the gate patterns 34 and the bit line patterns 69, may constitute a semiconductor device 115, according to illustrative embodiments.

According to the embodiments as described above, a ratio of an area occupied by semiconductor patterns on an active region can be increased in spite of continuously decreasing design rules. For this, gate patterns may be located on an active region at right angles to the active region, and bit line patterns may be located on an inactive region to intersect the gate patterns at right angles. Also, storage nodes may be located on the active region between the gate patterns and the bit line patterns. As a result, an alignment margin by which the storage nodes may overlap the active region can be increased between the gate patterns and the bit line patterns compared with the conventional art.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A semiconductor device comprising:
an active region in a semiconductor substrate, the active region comprising first, second and third regions sequentially arranged in the active region;
an inactive region in the semiconductor substrate defining the active region;
a plurality of gate patterns partially buried in the active region and the inactive region, each gate pattern being positioned between the first and second regions or between the second and third regions, intersecting the active region at right angles, and passing through the active region and the inactive region;
a bit line pattern on the gate patterns, intersecting the gate patterns at right angles, the bit line pattern overlapping the inactive region and comprising a predetermined region electrically connected to the second region of the active region;
an interlayer insulating layer covering the gate patterns and surrounding the bit line pattern to expose the bit line pattern; and
a plurality of storage nodes on the interlayer insulating layer and electrically connected to the active region, wherein a first storage node overlaps the first region and the inactive region and a second storage node overlaps the third region, the inactive region and the bit line pattern.

2. The device according to claim 1, wherein the second storage node is in contact with the bit line pattern on the third region of the active region.

3. The device according to claim 2, wherein the active region, the gate patterns, the bit line pattern, and the storage nodes are located at intersections of rows and columns of the semiconductor substrate.

4. The device according to claim 3, further comprising:
a plurality of neighboring active regions in the semiconductor substrate neighboring the active region, each neighboring active region comprising first, second and third regions sequentially arranged in the corresponding neighboring active region,
wherein the first, second and third regions of the active region respectively face the first, second and third regions of a neighboring active region located in a same row of the semiconductor substrate, and wherein the third region of the active region faces the first region of a neighboring active region located in a same column of the semiconductor substrate.

5. The device according to claim 4, wherein the gate patterns are in at least one row of the semiconductor substrate, the bit line pattern is in a column of the semiconductor substrate, and the gate patterns intersect the bit line pattern at right angles at the respective intersections of the at least one row and the column.

6. The device according to claim 5, wherein the bit line pattern is located at least in part in the inactive region between the active region and the neighboring active region located in the same row of the semiconductor substrate.

7. The device according to claim 6, wherein the first storage node is located at least in part on the active region and partially overlaps a bit line pattern adjacent to the active region.

8. The device according to claim 7, wherein, in the intersections among the rows and columns of the semiconductor substrate, storage nodes are defined between the bit line pattern and the adjacent bit line pattern and are arranged diagonally with respect to one another.

9. The device according to claim 8, wherein, in the intersections among the rows and columns of the semiconductor substrate, the storage nodes between the bit line pattern and the adjacent bit line pattern form a zigzag pattern on the active region with respect to the neighboring active regions.

10. The device according to claim 9, wherein, in the intersections among the rows and columns of the semiconductor substrate, storage nodes of neighboring bit line patterns are positioned diagonally from one another in different active regions in a first direction, and the storage nodes of the neighboring bit line patterns are positioned diagonally from one another in twos on each active region in a second direction perpendicular to the first direction.

11. A method of fabricating a semiconductor device, comprising:
forming an inactive region in a semiconductor substrate to define an active region;
forming two gate patterns in the active region and the inactive region to intersect the active region at right angles;
forming a first interlayer insulating layer on the active region to cover the gate patterns;
forming a bit line pattern on the first interlayer insulating layer to intersect the gate patterns at right angles, wherein the bit line pattern is formed on the inactive region adjacent to the active region and electrically connected to the active region between the gate patterns through the first interlayer insulating layer;
forming a second interlayer insulating layer on the first interlayer insulating layer to cover the bit line patterns; and
forming storage nodes which overlap the active region adjacent to the gate patterns, the inactive region, and the bit line pattern, and are electrically connected to the active region adjacent to the gate patterns through the first and second interlayer insulating layers.

12. The method according to claim 11, wherein forming the gate patterns comprises:
forming molding holes corresponding to the gate patterns in the semiconductor substrate;
forming a gate insulating layer in the molding holes;
forming gates on the gate insulating layer to partially fill the molding holes; and
forming gate capping patterns on the gates to fill the molding holes, respectively, and protrude from surfaces of the active region and the inactive region,
wherein the gates are formed of conductive material.

13. The method according to claim 12, wherein forming the bit line pattern comprises:
forming a bit line contact hole in the first interlayer insulating layer to expose the active region between the gate patterns;
forming a bit line contact to fill the bit line contact hole;
forming a bit line conductive layer and a bit line capping layer to cover the bit line contact; and
sequentially etching the bit line capping layer and the bit line conductive layer until the first interlayer insulating layer is exposed,
wherein the bit line contact is formed of conductive material, and a predetermined region of the bit line pattern is in contact with the bit line contact.

14. The method according to claim 13, wherein electrically connecting the storage nodes to the active region adjacent to the gate patterns comprises:
forming node contact holes in the first and second interlayer insulating layers to expose the active region adjacent to the gate patterns, the bit line contact hole being formed between the node contact holes;
forming node contacts using conductive material to fill the node contact holes; and
forming the storage nodes on the node contacts, respectively.

15. The method according to claim 14, wherein one of the storage nodes is in contact with the bit line pattern, and one of the node contacts.

16. The method according to claim 15, wherein the active region, the gate patterns, the bit line pattern, the node contacts, and the storage nodes are located at intersections of rows and columns of the semiconductor substrate.

17. The method according to claim 16, wherein neighboring active regions adjacent to the active region in a select row of the semiconductor substrate are formed in a horizontal direction to have the same center and area as the active region, and neighboring active regions adjacent to the active region in a select column of the semiconductor substrate are formed in a vertical direction to have the same center and area as the active region.

18. The method according to claim 17, wherein, in the intersections of the rows and columns of the semiconductor substrate, the gate patterns are formed in at least one row of the semiconductor substrate, the bit line pattern is formed in a column of the semiconductor substrate, and the gate patterns intersect the bit line pattern at right angles at the respective intersections.

19. The method according to claim 18, wherein, in the intersections of the rows and columns of the semiconductor substrate, the bit line pattern is formed in the inactive region between two neighboring active regions in the select row of the semiconductor substrate.

20. The method according to claim 19, wherein, in the intersections of the rows and columns of the semiconductor substrate, the storage nodes are formed on a select active region to partially overlap two neighboring bit line patterns adjacent to the select active region.

21. The method according to claim 20, wherein, in the intersections of the rows and columns of the semiconductor substrate, the storage nodes are defined between the bit line pattern and a neighboring bit line pattern adjacent to the select active region and formed to face each other in a diagonal direction.

22. The method according to claim 21, wherein, in the intersections of the rows and columns of the semiconductor substrate, the storage nodes and storage nodes of the neighboring bit line pattern are formed in a zigzag pattern on the active regions.

23. The method according to claim 21, wherein, in the intersections of the rows and columns of the semiconductor substrate, the storage nodes and storage nodes of two neighboring bit line patterns are diagonally formed on different active regions from one another in a first direction, and the storage nodes of each bit line pattern are diagonally formed in twos on each of the corresponding different active regions from one another in a second direction perpendicular to the first direction.
